(19) United States
(12) Patent Application Publication
(10) Pub. No.: US 2026/0353588 A1
(43) Pub. Date: Nov. 5, 2026

(54) LATCH INTERRUPT FOR LATCH MECHANISM OF INFORMATION PROCESSING DEVICE

(71) Applicant: HEWLETT PACKARD ENTERPRISE DEVELOPMENT LP, Spring, TX (US)

(72) Inventors: Brad Paul Dulian, Chippewa Falls, WI (US); Harvey John Lunsman, Chippewa Falls, WI (US); Michael Dustin Scott, Chippewa Falls, WI (US)

(21) Appl. No.: 19/194,835

(22) Filed: Apr. 30, 2025

(51) Int. Cl. H05K 7/14

(52) U.S. Cl. CPC H05K 7/1489; H05K 7/1401

(57) ABSTRACT

An information processing system comprises a system chassis that removably receives multiple pluggable blades. A blade includes a latch mechanism to secure the blade in the system chassis. The latch mechanism includes mechanically coupled links that are actuatable in one direction to inject the blade into an installed position in the system chassis and in another direction to eject the blade from the installed position. The blade includes a latch interrupt to selectively engage with one of the links and disable actuation of the latch mechanism or disengage from the link and enable actuation of the latch mechanism, based on a position of the blade within the system chassis. The latch interrupt may disable actuation of the latch mechanism until the blade reaches an injection-ready position in the system chassis, whereupon the latch interrupt is automatically moved to enable actuation of the latch mechanism.

### INTRODUCTION

Some information processing systems have a blade-style architecture in which a single shared system chassis is configured to removably house multiple pluggable servers or other pluggable information processing devices (such as networking devices). Such a system may be referred to herein as a blade system, and the individual pluggable devices may be referred to herein as blades. Each blade may have its own individual device chassis supporting a system board with a processor (as well as other information processing components), and each blade is configured to be pluggable into a corresponding bay of the system chassis. In this context, “pluggable” means that the blade is removably installable in the bay and that during the insertion into the bay electrical connectors thereof blind mate with electrical connectors of the system chassis. Note that some manufacturers or users may use terminology other than “blade” to refer to systems that have a blade-style architecture as defined herein. For example, some may refer to a blade using an alternative term such as “tray” or “node.” However, the terms “blade system” and “blade” are used broadly herein, as defined above, and are not limited to systems or devices which are explicitly named a “blade system” or “blade” by the manufacturer or others.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic block diagram illustrating an information processing system and information processing device with a latch mechanism and a latch interrupt.

FIGS. 2-5 are schematic block diagrams illustrating an example insertion sequence of the information processing device of FIG. 1 into a bay. FIG. 2 shows a first stage of the insertion sequence in which the latch interrupt is not yet engaged with a release feature. FIG. 3 shows a second stage of the insertion sequence where the latch interrupt has made initial engagement with the release feature. FIG. 4 shows a third stage of the insertion sequence where the blade has reached an injection-ready position and the latch interrupt has been moved to an enabling state. FIG. 5 shows a fourth stage of the insertion sequence where the blade has reached an installed position.

FIGS. 6-9 are schematic plan views illustrating an example insertion sequence of another information processing device with a latch mechanism and a latch interrupt into a bay. FIG. 6 shows a first stage of the insertion sequence in which the latch interrupt is not yet engaged with a release feature. FIG. 7 shows a second stage of the insertion sequence where the latch interrupt has made initial engagement with the release feature. FIG. 8 shows a third stage of the insertion sequence where the blade has reached an injection-ready position and the latch interrupt has been moved to an enabling state. FIG. 9 shows a fourth stage of the insertion sequence where the blade has reached an installed position.

FIG. 10 is a partial perspective view of another information processing device with a latch mechanism and a latch interrupt.

FIGS. 11-14 are plan views illustrating an example insertion sequence of the information processing device of FIG. 10. FIG. 11 shows a first stage of the insertion sequence in which the latch interrupt is not yet engaged with release feature. FIG. 12 shows a second stage of the insertion sequence where the latch interrupt has made initial engagement with the release feature. FIG. 13 shows a third stage of the insertion sequence where the blade has reached an injection-ready position and the latch interrupt has been moved to an enabling state. FIG. 14 shows a fourth stage of the insertion sequence where the blade has reached an installed position.

### DETAILED DESCRIPTION

In many blade systems, the blades will include latch mechanisms which can engage with the system chassis to secure the blade in the system chassis. In many cases, these latch mechanisms may also be configured to apply forces to the system chassis to assist the user in installing and removing the blade from the system chassis. This assistance may be referred to as injection (during installation) and ejection (during removal). The injection and ejection assistance provided by the latch mechanism may help to overcome friction forces that may resist the final stage of insertion or the initial stage or removal of the blade. Such friction forces may arise due to the concurrent mating (during insertion) or decoupling (during removal) of multiple electrical connectors of the blade with connectors of the system chassis. These resistance forces can be relatively large, in some cases too large for a user to comfortably overcome unaided, particularly on a repeated basis. For instance, in some systems the resistance forces can be as high as 400 lbs. Thus, the latch mechanisms may be relatively robust to supply sufficiently strong injection and ejection forces to assist in overcoming the resistance. Because such latch mechanisms help with injection and ejection, they are also sometimes referred to as an injector, an ejector, an injector/ejector, or other similar terms, but they will be referred to herein as latch mechanisms.

Some of these latch mechanisms may utilize a series of mechanically coupled links arranged to convert a manually applied force supplied by a user into an injection or ejection force applied to the system chassis, with the links providing a mechanical advantage such that the injection/ejection force is amplified relative to the manually applied force. However, some of these latch mechanisms can cause damage to the system chassis if actuated improperly. In particular, under certain circumstances, if the latch mechanism is actuated to a latched state before the blade has reached an injection-ready position in the bay, then a link of the latch mechanism may contact and cause damage to a part of the system chassis. These latch mechanisms may be very strong (to overcome the high resistance forces), and therefore they may easily bend sheet metal of the system chassis or cause other damage if actuated prematurely.

For example, in some latch mechanisms the links may include a lever that a user can manually actuate (pivot), a cam that engages the system chassis, and one or more gears mechanically coupling the lever to the cam. The cam may include a latching recess defined between two teeth, with the latching recess arranged to engage (receive) a latching protrusion of the chassis. When the blade is at the injection-ready position, the latching protrusion will engage with (be received in) the latching recess, and thus rotation of the cam in this position causes the teeth of the cam to push forward or rearward (depending on the direction of cam rotation) against the latching protrusions, thereby generating injection or ejection forces. However, if the blade has been inserted into the bay to a position short of the injection-ready position, then when the cam is rotated it is possible that one of its teeth will push outwardly against the latching protrusion, rather than the latching protrusion being received in the latching recess. This outward pressing of the teeth against the latching protrusion can bend or otherwise damage part of the system chassis, such as by deforming the wall of the system chassis to which the latching protrusion is attached.

To address these issues, the present disclosure provides a latch interrupt that automatically disables actuation of a latch mechanism of a blade until the blade is at the injection-ready position in the system chassis, and which automatically enables actuation of the latch mechanism once the blade reaches the injection-ready position. Thus, the latch interrupt can prevent premature actuation of the latch mechanism and the associated damage this may cause. The latch interrupt may be a mechanical interrupt mechanism which performs the above described disabling and enabling without requiring electrical or human intervention to monitor, control, actuate, or otherwise operate the interrupt (aside from the action of inserting the blade into the bay).

In some examples, the latch interrupt comprises an interrupt arm which is attached to a device chassis of the blade and moveable between two states: a disabling state and an enabling state. In the disabling state, the interrupt arm engages with one of the links in the latch mechanism and disables actuation of the latch mechanism by physically preventing the latch mechanism from moving from an unlatched state to a latched state. In an enabling state, the interrupt arm is disengaged from the link and allows the latch mechanism to be actuated in the normal fashion. The interrupt arm is arranged to automatically enter the enabling state in response to the device chassis being inserted into the system chassis to the injection-ready position. More specifically, the interrupt arm may be configured to engage with (e.g., contact) a release feature on the system chassis, and this engagement causes the interrupt arm to move to the enabling state. The interrupt arm and release feature may be positioned such that the movement of the interrupt arm to the enabling state occurs at (or very near) the moment when the blade reaches the injection-ready position.

In some examples, the interrupt arm is configured to automatically enter the disabling state when the latch is moved to the unlatched state and the blade has been moved away from the injection-ready position. For instance, a biasing element, such as a spring, may be provided to supply a biasing force to bias the interrupt arm towards the disabling state. When the blade is in the installed position and the latch mechanism is in the latched state, the interrupt arm is blocked from moving to the disabling state, but when the latch mechanism is moved to the unlatched state and the blade moved away from the injection-ready position, the interrupt arm is no longer blocked and therefore the biasing force can automatically move the interrupt arm to the disabling state. Thus, when the blade is ejected from the system chassis, the latch interrupt may be automatically moved to the disabling state, thus resetting the latch interrupt to prevent premature actuation of the latch mechanism the next time the blade is installed in the system chassis.

Turning now to the figures, various devices, systems, and methods in accordance with aspects of the present disclosure will be described.

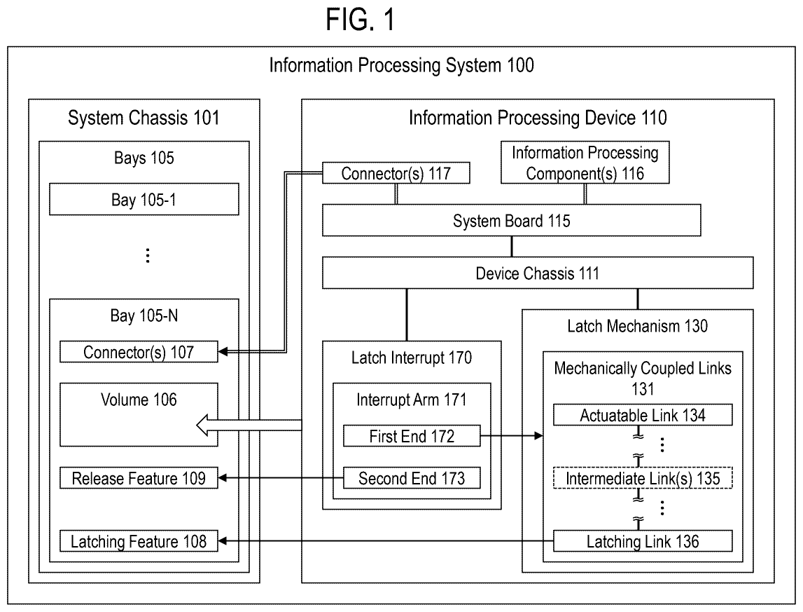

FIG. 1 is a schematic diagram conceptually illustrating a system 100, which includes a system chassis 101 and an information processing device 110 with a latch interrupt 170. FIG. 1 is schematic and conceptual in nature and is not intended to illustrate spatial relationships, shapes, dimensions, or other structural details unless otherwise mentioned. Moreover, FIG. 1 is not intended to exhaustively depict all aspects of the system 100, information processing device 110, or latch interrupt 170. Elements illustrated in FIG. 1 may be included in numbers and/or arrangements that differ from the illustrated numbers or arrangements, some examples may include elements that are not illustrated in FIG. 1, and/or some examples may omit one or more of the elements that are illustrated in FIG. 1. FIG. 1 illustrates the full system 100 to aid understanding, but some examples disclosed herein may comprise just the information processing device 110 (without system chassis 101).

In FIG. 1, solid lines extending between boxes depict engagement (e.g., attachment, coupling, or other engagement) between components, and doubled solid lines extending between boxes depict an electrical connection between components. Such lines depicting engagement or electrical connection which end in arrows depict removable engagements/connections or engagements/connections that are intermittent (i.e., occur in some states but not in others).

The system chassis 101 comprises one or more walls and other support structures configured to form an enclosure defining a plurality of bays 105. These bays 105 are configured to removably receive pluggable information processing devices installed therein, respectively. In other words, the information processing system 100 has a blade-style architecture, and the individual information processing devices installable therein may also be referred to herein as blades. These blades may include server blades, networking device blades, or other information processing devices. The information processing device 110 is one example of these blades, and it may thus also be referred to herein as blade 110.

FIG. 1 shows N bays 105, including bays 105-1 to 105-N, wherein N is any integer equal to or greater than 2. Internal components of a bay 105 are shown in FIG. 1 in relation to bay 105-N, but it should be understood that the other bays 105 may also have some or all of the same components. In particular, each bay 105 may include an internal volume 106 into which a blade may be inserted. The volume 106 may be defined and bounded by support structures of the system chassis 101, such as walls of the chassis, guide and/or support feature (e.g., rails) that engage with a blade as it is inserted into the volume 106 to guide the blade into an installed position and/or support the blade, and so on. The bay 105 also includes one or more electrical connectors 107 which are disposed in or adjacent to the volume 106 such that the electrical connectors 107 can blind mate with corresponding electrical connectors of a blade installed in the volume 106, such as electrical connectors 117 of the information processing device 110. The bay 105 also includes a latching feature 108 and a release feature 109 to engage with a latch mechanism and a latch interrupt, respectively, of a blade, such as a latch mechanism 130 and a latch interrupt 170 of blade 110, which will be described in greater detail below.

In some examples, structural features of the bays 105, such as the sizes and/or shapes of the volume 106 or the sizes, shapes and/or locations of latching feature 108 and/or release feature 109, may vary between bays 105. For instance, in some examples, one or more bays 105 may be configured to receive one form factor of blade while one or more other bays 105 may be configured to receive another form factor of blade. Or, in other examples, the bays 105 may be configured to receive the same form factor of blades but with the blades installed in varying (e.g., alternating) orientations, resulting in different (e.g., mirrored) layouts for the bays 105. In still other examples, the internal components and layout of the bays 105 may all be structurally identical.

The system 100 may further comprise, in some examples, a backplane (not illustrated) which is connected to some or all of the connectors 107 of the bays 105. This backplane may electrically connect the blades installed in the system chassis 101 to one another and/or to other devices to enable exchange of data therebetween. These other devices may include a system controller (not illustrated) of the system 100 in some examples, and/or other devices external to system 100. The system 100 may also include power delivery devices (not illustrated) that supply power to the blades through the electrical connectors 107 and cooling systems (not illustrated) (e.g., fans, liquid cooling systems, etc.) that supply cooling resources (e.g., cool air, cool liquid, etc.) to the blades.

The information processing device 110 (“blade 110”) comprises a device chassis 111, a system board 115, information processing components 116 electrically connected to the system board 115, one or more latch mechanisms 130, and one or more latch interrupts 170. These will be described in greater detail in turn below.

The device chassis 111 comprises one or more walls and/or other support structures configured to support the other components of the blade 110. In some examples, device chassis 111 forms a housing that encloses/houses the system board 115. In other examples, device chassis 111 may be a tray which supports, but does not fully enclose, the system board 115. The device chassis 111 is configured to be installable in one of the bays 105 by insertion into the volume 106 of the bay 105 and engagement with various feature in the bays 105, with the installation completing upon the device chassis 111 reaching an installed position where blind-mating with the electrical connectors 107 completes.

System board 115 may be a motherboard, host processor module, or other printed circuit assembly to which a processor is mounted. This processor is one of the information processing components 116 and may include or be a part of a central processing unit (CPU), a graphics processing unit (GPU), a system-on-chip (SoC), an application specific integrated circuit (ASIC), or any other integrated processing circuitry. Additional information processing components 116 may also be mounted on the system board 115, in some examples, such memory modules. Furthermore, information processing components 116 may also include additional peripheral components that are not mounted directly to the system board 115 but which are electrically connected thereto (e.g., by cables), such as storage drives.

In addition, the blade 110 includes the electrical connectors 117 mentioned above, which are electrically connected to the system board 115 (in some cases, mounted directly to the system board 115, in other cases coupled thereto by cables). When the blade 110 is in a fully installed position in a bay 105, the electrical connectors 117 physically mate and electrically connect with electrical connectors 107 in the bay 105.

The latch mechanism 130 is coupled to the device chassis 111 and configured to latch the blade 110 to the system chassis 101 when the blade 110 is in the fully installed position. The latch mechanism 130 is actuatable between a latched state and an unlatched state. In the latched state, the latch mechanism 130 engages the latching feature 108 in the system chassis 101 to latch (secure) the blade 110 in the bay 105 by preventing translation of the blade 110 relative to the system chassis 101 at least in a removal direction. In the unlatched state, the latch mechanism 130 releases the blade 110 from the system chassis 101, allowing the blade 110 to be removed.

In addition, the latch mechanism 130 is configured to assist with injection of the blade 110 into an installed position in the bay 105 and ejection of the blade 110 from the installed position. Specifically, if the blade 110 is at an injection-ready position in the bay 105, then actuation of the latch mechanism 130 from the unlatched state to the latched state will cause the latch mechanism 130 to press against the latching feature 108 and inject the blade 110 into the installed position in the bay 110. Injecting the blade 110 means applying forces to the system chassis 101 that cause the blade to translate relative to the system chassis 101 in an insertion direction from the injection-ready position into the installed position. Conversely, if the blade 110 is at the installed position in the bay 105, then actuation of the latch mechanism 130 from the latched state to the unlatched state will cause the latch mechanism to press against the latching feature and eject the blade 110 from the installed position. Ejecting the blade 110 means applying forces to the system chassis 101 that cause the blade to translate relative to the system chassis 101 in a removal direction (opposite the insertion direction) from the installed position back to the injection-ready position.

The latch mechanism 130 comprises a series of mechanically coupled links 131. The links 131 may be configured to provide a mechanical advantage such that actuation forces supplied to the latch mechanism 130 produce proportionally larger injection and injection forces applied by the latch mechanism 130, with the proportional increase depending on the magnitude of the mechanical advantage. The mechanical advantage may be achieved, for example, by configuring the links 131 such that actuation thereof over a given actuation distance produces injection/ejection movement over a proportionally shorter injection/ejection distance, with the mechanical advantage equaling the ratio of these distances. For example, the links may include levers, gears with different gear ratios, screws/worm gears, and/or any other known mechanisms for providing mechanical advantage.

One of the links 131 includes an actuatable link 134 that can be actuated (moved) between two poses to cause the latch mechanism 130 to move between the latched and unlatched states. These poses may be referred to as latched and unlatched poses of the actuatable linked 134. Actuation of the actuatable link 134 in one direction—i.e., from the latched pose to the unlatched pose—causes the latch mechanism 130 to move from the latched state to the unlatched state, while actuation of the actuatable link 134 in the opposite direction—i.e., from the unlatched pose to the latched pose—causes the latch mechanism 130 to move from the unlatched state to the latched state. In some examples, the actuatable link 134 comprises a lever pivotably coupled to the device chassis 111, which can be manually actuated by a user grasping and pivoting the lever. In other examples, the actuatable link 134 may be a bolt or screw which may be actuated by rotating the bolt or screw (e.g., manually or using a tool, such as an electric driver). In other examples, the actuatable link 134 may take some other form. Because actuation of the actuatable link 134 drives actuation of the latch mechanism 130 as a whole, such actuation may be interchangeably referred to herein as actuation (or movement) of the actuatable link 134 or actuation (or movement) of the latch mechanism 130.

Another one of the links 131 comprises a latching link 136 which is configured to engage with the latching features 108 to latch the blade 110 in the bay 105, inject the blade 110, eject the blade 110, or release the blade 110, depending on the state of the latch mechanism 130. The latching link 136 is movable between a first pose corresponding to the latched state and a second pose corresponding to the unlatched state in response to actuation of the actuatable link 134. These poses may be referred to as latched and unlatched poses of the latching link 136. The mechanical coupling between the links 131 is such that when the actuatable link 134 is in its latched pose the latching link 136 is also in its latched pose, and when the actuatable link 134 is in its unlatched pose the latching link 136 is also in its unlatched pose, and movement of the actuatable link 134 between its latched and unlatched poses causes concurrent movement of the latching link 136 between its latched and unlatched poses. When the latching link 136 is in its latched pose, it engages the latching feature 108 to latch the blade 110 to system chassis 101. When the latching link 136 is in its unlatched pose, it releases from the latching feature 108 to release the blade 110 from the system chassis 101. Movement of the latching link 136 from the latched pose to the unlatched pose causes the latching link 136 to press against the latching features 108 to eject the blade 110. Movement of the latching link 136 from the unlatched pose to the latched pose causes the latching link 136 to press against the latching features 108 to inject the blade 110.

In some examples, the latching link 136 comprises a cam that is rotatably coupled to the device chassis 111 and configured to engage the latching features 108 in a manner that converts rotational motion of the cam into translational motion of the blade 110 relative to the system chassis 101. In some of these examples, the cam may comprise a latching recess defined between two latching teeth, and the latching feature 108 of the system chassis 101 may comprise a protrusion which is received within the latching recess when the cam engages therewith. In other examples, the cam may comprise a latching protrusion and the latching feature 108 of the system chassis 101 may comprise a recess into which the latching protrusion extends when the cam engages therewith. In either case, actuation of the latch mechanism 130 causes rotation of the cam between its latched and unlatched poses, which in turn causes the cam to press against the latching feature 108 and move the blade 110 relative to the system chassis 101.

In some examples, one or more intermediate links 135 may be disposed between the actuatable link 134 and the latching link 136 to mechanically couple these together such that actuation of the actuatable link 134 causes movement of the latching link 136. In some examples, the actuatable link 134 includes a first gear, latching link 136 includes a second gear, and the intermediate links 135 include one or more intermediate gears, with the gears connected in series with gear teeth thereof enmeshed so as to all rotate together. In some examples, intermediate links 135 are omitted and actuatable link 134 is directly coupled to latching link 136.

In some examples, the latch mechanism 130 may be disposed adjacent a front lateral corner of the device chassis 111. This may allow for a portion of latch mechanism 130 to be accessible from a front of the device chassis 111 while also allowing the latch mechanism 130 to engage with a side wall of the system chassis 101. For example, a portion of the actuatable link 134 (e.g., a lever handle) may protrude forward through the front panel of the device chassis 111 to allow manual actuation from outside the device chassis 111 by a user positioned in front of the system chassis 101. Furthermore, a latching link 136 may protrude laterally through a side wall of the device chassis 111 to engage with the latching feature 108 on a side wall of the system chassis 101.

In some examples, the blade 110 may include multiple of the latch mechanisms 130. For example, a latch mechanism 130 may be provided in each of the two front-side corners of the device chassis 111, each configured to engage with an opposite side wall of the system chassis 101. In some examples where multiple latch mechanisms 130 are present, the latch mechanisms 130 may be mechanically coupled together so as to coordinate their motion such that they are always actuated together in the same direction. For example, a rack-and-pinion linkage may be used to mechanically couple the latch mechanisms 130 together.

The latch interrupt 170 is coupled to the device chassis 111 and configured to selectively disable and enable actuation of the latch mechanism 130 by engagement with and disengagement from one of the links 131, respectively, based on a position of the device chassis 111 within the system chassis 101. More specifically, the latch interrupt 170 may be configured to engage a release feature 109 of the system chassis 101 during insertion of the device chassis 111 into the system chassis 101 and to be moved by the engagement from a disabling state to an enabling state. In the disabling state, the latch interrupt 170 disables actuation of the latch mechanism 130 (specifically, actuation from the unlatched state to the latched state). In the enabling state, the latch interrupt 170 enables actuation of the latch mechanism 130.

The latch interrupt 170 may comprise an interrupt arm 171 which has a first end 172 and a second end 173. The first end 172 may selectively contact one of the links 131 to disable actuation of the latch mechanism 130 by physically preventing (blocking) the link 131 from moving. The second end 173 may be configured to engage (e.g., contact) the release feature 109 as the blade 110 reaches a predetermined position in the bay 105, with the engagement causing the interrupt arm 171 to move such that the first end 172 disengages from the link 131, moving the latch interrupt 170 to the enabling state. The interrupt arm 171 may be configured to move between two poses, including a first pose and a second pose. In moving between the first and second poses, the interrupt arm 171 passes through a first range of poses, which includes the first pose, and a second range of poses, which includes the second pose. The disabling state of the latch interrupt 170 occurs whenever the interrupt arm 171 is in a pose in the first range of poses, whereas enabling state of the latch interrupt 170 occurs whenever the interrupt arm is in a pose in the second range of poses. In other words, the disabling state corresponds to the interrupt arm 171 being in the first pose or near the first pose in the first range, while the enabling state corresponds to the interrupt arm 171 being in the second pose or near the second pose in the second range. Movement of the interrupt arm 171 from the first range to the second range corresponds to a transition of the latch interrupt 170 from the disabling state to the enabling state.

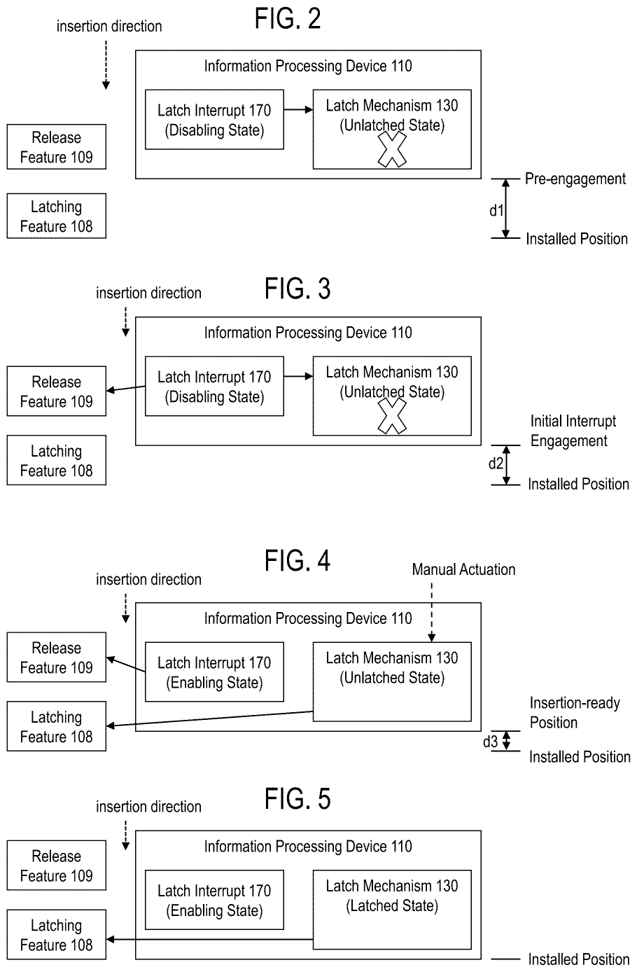

For example, FIGS. 2-5 illustrate an insertion sequence of the blade 110 into a bay 105 (only some portions of the devices are illustrated in FIGS. 2-5). FIG. 2 illustrates a first insertion stage in which the blade 110 is a distance d1 from a fully installed position. In this position, referred to herein as a pre-engagement position, the blade 110 is not yet advanced far enough into the bay 105 to engage with the release feature 109 or latching feature 108. Moreover, the latch mechanism 130 is in the unlatched state and the latch interrupt 170 is in the disabling state. Thus, in this stage of insertion, the latch interrupt 170 prevents actuation for the latch mechanism 130 to the latched state, as indicated by the large “X” in FIG. 2. This may be beneficial because, at this first stage, the blade 110 has not yet reached an injection-ready position, and actuation of the latch mechanism 130 might cause damage.

Continued advancement of the blade 110 into the bay 105 along the insertion direction results in the latch interrupt 170 eventually engaging with the release feature 109 of the system chassis 101. For example, the latch interrupt 170 may physically contact (collide with) the release feature 109. The position of the blade 110 where this engagement initially occurs is a second stage of insertion and is shown in FIG. 3. In this second stage, the blade 110 is a distance d2 from the installed position, where d2 <d1. This position of the blade 110 may be referred to herein as an initial interrupt engagement position. At this second stage, the engagement with the latch interrupt 170 has just begun, and thus the latch interrupt 170 has not yet been moved out of the disabling state. Thus, actuation of the latch mechanism 130 continues to be prevented. This may be beneficial because, at this second stage, the blade 110 has still not yet reached an injection-ready position, and actuation of the latch mechanism 130 might cause damage.

Continued advancement of the blade 110 into the bay 105 along the insertion direction results in the latch interrupt 170 being moved by the release feature 109 from the disabling state towards the enabling state. Eventually, the blade 110 reaches a position where the latch interrupt 170 is moved fully to the enabling state, thereby releasing the latch mechanism 130 and allowing manual actuation thereof. This position corresponds to a third stage of insertion, and is shown in FIG. 4. In this third stage, the blade 110 is a distance d3 from the installed position, where d3<d2. Moreover, the release feature 109 and the latch interrupt 170 may be mutually arranged such that this position of the blade 110 at which the latch interrupt 170 disengages from the latch mechanism and enters the enabling state also corresponds to an injection-ready position. In other words, the latch interrupt 170 may enter the enabling state at the same time that the blade 110 reaches an injection-ready position. An injection-ready position is a position of the blade 110 at which the latch mechanism 130 can, if actuated to the latched position, properly engage with the latching features 108 of the system chassis 101 to inject the blade 110 the rest of the way to the installed position. In contrast, a position that is not an injection-ready position would include a position in which the latch mechanism 130 cannot engage with the latching feature 108, or a position in which the latch mechanism 130 can engage with the latching feature 108 but in a dysfunctional or anomalous manner that may cause damage and/or prevent injection. (In some examples, there may be a small range of positions that are all injection-ready positions, rather than just one single injection ready position; in other examples, there is just one injection-ready position.)

At the third stage, because the latch interrupt 170 is in the enabling state, actuation of the latch mechanism 130 is allowed. Actuation of the latch mechanism 130 towards the latched state causes the latch mechanism 130 to engage with and press against the latching feature 108, which forces the blade 110 to advance farther into the bay 110. Eventually, the latch mechanism 130 reaches the latched state, whereupon the blade 110 is in the fully installed position. This fourth stage of insertion is shown in FIG. 5. In this stage, the latch mechanism 130 latches (secures) the blade 110 in the bay 105.

Withdrawal of the blade 110 from the bay 105 may proceed in the reverse of the insertion procedure described above. Specifically, in the state shown in FIG. 5, the latch mechanism 130 may be actuated towards the unlatched state, which causes the latch mechanism to press against the latching feature 108 and force the blade 110 to move in a removal direction, opposite the insertion direction. Eventually, when the latch mechanism 130 reaches the unlatched state, the blade 110 is moved to the position shown in FIG. 4. A user may then continue to withdraw the blade 110, and as they do so the latch interrupt 170 may move towards the disabling state and eventually reengage with the latch mechanism 130. By the time that the blade 110 reaches the position shown in FIG. 3, the latch interrupt 170 will have fully reached the disabling state and may prevent actuation of the latch mechanism 130 to the latched state. The user may then move the blade the rest of the way out of the bay 105, including moving through the position shown in FIG. 2.

In some examples, the latch interrupt 170 may further comprise a biasing element (not illustrated), such as a spring, magnet, or other biasing element. This biasing element may apply a biasing force (e.g., spring force, magnetic force, etc.) to the interrupt arm 171 which urges the interrupt arm 171 towards the disabling state, and more specifically towards the first pose. In other words, the biasing element biases the interrupt arm 171 to the disabling state (first pose). This means that the disabling state is the neutral or default state of the interrupt arm 171 and the interrupt arm 171 will tend to automatically return to this disabling state unless prevented from doing so by application of an outside force. This biasing force is what may return the latch interrupt 170 to the disabling state during withdrawal of the blade 110 from the bay 105, as described above. While the blade 110 is in the fully installed position (FIG. 5), the release feature 109 and/or the latch mechanism 130 in the latched state may hold the latch interrupt 170 in the enabling state by physically blocking movement of the interrupt arm 171, thus preventing the biasing element from returning the latch interrupt 170 to the disabling state. However, once the latch mechanism 130 is in the unlatched state and blade 110 has been moved sufficiently far from the installed state, the release feature 109 and latch mechanism 130 will no longer hold the latch interrupt 170 in the enabling state, allowing the biasing force to automatically return the latch interrupt 170 to the disabling state. In some examples, the latch interrupt 170 will first enter the disabling state just after the blade 110 has been withdrawn past the insertion-ready position (FIG. 4). Note that the interrupt arm 171 may not yet have moved fully to the first pose at this time, but it may have entered into the first range of poses and thus it has entered the disabling state. The interrupt arm 171 may continue to move through the first range towards the first pose as the blade 110 continues to be withdrawn farther from the insertion-ready position.

In some examples, the latch interrupt 170 further comprises a pivot coupling (not illustrated) which pivotably couples the interrupt arm 171 to the device chassis 111, in which case the movement of the interrupt arm 171 is a pivoting (rotating) movement. The pivot coupling may be coupled to the interrupt arm 171 between the first end 172 and the second end 173 such that the second end 173 may be pushed in one direction by the release feature 109, which causes the interrupt arm 171 to pivot and the first end 172 to move in the opposite direction. In such examples, the first pose of the interrupt arm 171 is a first orientation of the interrupt arm 171 and the second pose of the interrupt arm 171 is a second orientation of the interrupt arm 171.

In other examples, instead of the pivot coupling, the latch interrupt 170 further comprises a translational coupling (not illustrated) which movably couples the interrupt arm 171 to the device chassis 111 such that the interrupt arm 171 can move in translation relative to the device chassis 111. For example, the interrupt arm 171 may be configured as a plunger which translates along an axis into and out of engagement with one of the links 131 to prevent motion of the link 131. In such examples, the first pose of the interrupt arm 171 is a first position of the interrupt arm 171and the second pose of the interrupt arm 171 is a second position of the interrupt arm 171. In some examples, the interrupt arm 171 translates parallel to the insertion direction in response to contact with the release feature 109. In other examples, the interrupt arm 171 may translate in a direction transverse (e.g., perpendicular) to the insertion direction in response to contact with the release feature 109, in which case the second end 173 and/or the release feature 109 may include a sloped surface arranged to convert the insertion motion of the blade 110 into the transverse movement of the interrupt arm 171.

In some examples, the engagement between the second end 173 of the interrupt arm 171 and the release feature 109 comprises physical contact. For example, the second end 173 may protrude out of the device chassis 111 so that it can physically contact the release feature 109 as the blade 110 is inserted into the bay 105. In some examples, this protrusion may also enable a user to manually move the latch interrupt 170 to the enabling state, if desired (e.g., to allow actuation of the latch mechanism 130 outside of the system chassis 101, such as for storage or maintenance).

In other examples, the engagement between the second end 173 and the interrupt arm 171 does not involve contact. For example, one of the second end 173 and the release feature 109 may comprise a magnet and the other may comprise another magnet or a magnetically susceptible material (e.g., iron, steel) and thus when the second end 173 and the release feature 109 are sufficiently close, magnetic fields generated by the magnet(s) will apply magnetic forces to the second end 173 which cause the interrupt arm 171 to move.

In some examples in which multiple latch mechanisms 130 are provided, each may have its own latch interrupt 170. However, in some examples in which multiple latch mechanisms 130 are provided and they are mechanically coupled together, it may be sufficient for one latch mechanism 130 to have a latch interrupt 170, as the disabling of one latch mechanism 130 may also result in the disabling of the other latch mechanism 130 due to the mechanical coupling therebetween.

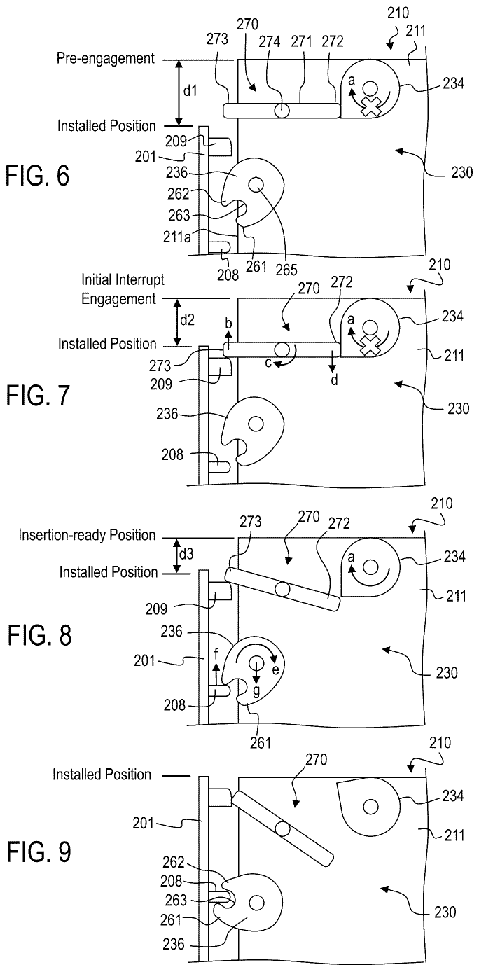

Turning now to FIGS. 6-9, an example latch mechanism 230 and latch interrupt 270 will be described. The latch mechanism 230 and latch interrupt 270 are example implementations of the latch mechanism 130 and latch interrupt 170 described above. Thus, some components thereof are similar to (e.g., example implementations or configuration of) corresponding components already described above. Corresponding components may be referred to using reference numbers having the same last two digits, such as 171 and 271. It should be understood that the latch mechanism 230 and latch interrupt 270 are possible implementations of the latch mechanism 130 and latch interrupt 170, but the latch mechanism 130 and latch interrupt 170 are not limited to these examples.

In this example, the latch mechanism 230 comprises an actuatable link 234 that is rotatably (pivotably) coupled to device chassis 211. For example, the actuatable link 234 may comprise a lever, although only a proximal end thereof is illustrated in FIGS. 6-9, with a lever handle portion thereof being omitted from the illustration. Or the actuatable link 234 may comprise some other form of link that is rotatable, such as a crank, knob, screw, worm gear, etc.

Furthermore, in this example, the latch mechanism 230 comprises a latching link 236 in the form of a cam (“cam 236”) rotatably coupled to device chassis 211 adjacent a lateral side 211a thereof. The cam 236 includes two cam teeth 261 and 262, a latching recess 263, and a pivot 265 rotatably coupling the cam to device chassis 211. The cam teeth 261 and 262 define the latching recess 263 therebetween and protrude laterally beyond the lateral side of the device chassis 211 in a latched state of the latch mechanism 230 to engage with a latching feature 208 of the system chassis 201, as shown in FIG. 9. In this example, the latching feature 208 is a protrusion from a side wall of the system chassis 201 which is configured to be received within the latching recess 263.

The latch mechanism 230 also includes one or more intermediate links mechanically coupling actuatable link 234 to latching link 236 such that rotation of the actuatable link 234 causes rotation of the latching link 236 in a same direction (i.e., they both rotate clockwise together or both rotate counterclockwise together). Of course, in other examples (not illustrated), the actuatable link and latching link could be mechanically coupled to rotate in opposite directions, instead of the same direction. In still other examples (not illustrated), one or both of the links are configured to move in translation, rather than rotation. The intermediate links are not shown in FIGS. 6-9 to avoid obscuring other details.

In this example, the latch interrupt 270 comprises a latch interrupt arm 271 that is pivotably coupled to the device chassis 211 by a pivot 274.

Aspects of the latch mechanism 230 and the latch interrupt 270 will be described below in relation to an insertion sequence shown in FIGS. 6-9. This insertion sequence in FIGS. 6-9 has insertion stages that are more specific examples of the insertion stages shown in FIGS. 2-5.

FIG. 6 shows a first stage of insertion, which is an example of the first stage of insertion shown in FIG. 2. In this stage, the latch mechanism 230 is in an unlatched stage and the latch interrupt 270 is in the disabling state. Specifically, the interrupt arm 271 is in a first orientation (first pose) with the first end 272 of interrupt arm 271 in contact with the actuatable link 234 such that it physically prevents (blocks) rotation of the actuatable link 234 in the direction “a” shown in FIG. 6, which is a direction of rotation corresponding to actuation of the latch mechanism 230 to the latched state.

As the blade 210 is advanced from the first stage farther into the system chassis 201, eventually the second end 273 of the interrupt arm 271 collides with the release feature 209, which in this example is a protrusion from a side wall of the system chassis 201. This state is shown in FIG. 7 and is an example of the second stage shown in FIG. 3.

As the blade 210 continues to be advanced from the second stage farther into the system, the release feature 209 will push the second end 273 of the interrupt arm 271 to move in the direction “b” shown in FIG. 7, which creates a torque causing the interrupt arm 271 to rotate in the direction “c” shown in FIG. 7, which in turn causes first end 272 of interrupt arm 271 to move in direction “d” shown in FIG. 7. This movement corresponds to the interrupt arm 271 moving through the first range of poses corresponding to the disabling state, and thus the latch interrupt 260 remains disabled during this movement. However, eventually, the interrupt arm 271 will have moved far enough that it leaves the first range of poses and enters the second range of poses, at which point the first end 272 ceases to block the actuatable link 234, allowing the actuatable link 234 to be actuated in the direction “a”. This corresponds to a transition point of the latch interrupt 270 from the disabling state to the enabling state, in which it no longer prevents actuation of the latch mechanism 230.

This state in which the first end 272 initially disengages from (ceases to block rotation of) the actuatable link 234 is shown in FIG. 8. This corresponds to the third stage illustrated in FIG. 4. In this stage, the blade 210 is positioned in the bay at a injection-ready position. This means that, in this position, actuation of the latch mechanism 230 to the latched state by rotation of actuatable link 234 in direction “a” will cause the cam 236 to properly engage with the latching feature 208 and insert the blade 210 into the installed position. In this position, the cam tooth 262 may be engaged with forward edge of the latching feature 208, as shown in FIG. 8. Rotation of the actuatable link 234 in direction “a” causes cam 236 to rotate in direction “e,” which raises tooth 261 into contact with a trailing edge of the latching feature 208 and, with continued rotation, causes cam tooth 261 to push against latching feature 208 in direction “f” shown in FIG. 8. This causes a reaction force which pushes the blade 210 to move in direction “g” relative to device chassis 201, thus moving blade 210 into the installed position.

The installed position of the blade 210 is shown in FIG. 9, and corresponds to the fourth stage illustrated in FIG. 5. This position of the blade 210 is reached when the latch mechanism 230 has been moved fully to the latched state. In this state, the latching feature 208 is received in the latching recess 263, with the can cam teeth 261 and 262 on opposite sides thereof, thus latching the blade 210 to the system chassis 201. Moreover, the latch interrupt 270 is held in the enabled state, allowing actuation of the latch mechanism 230.

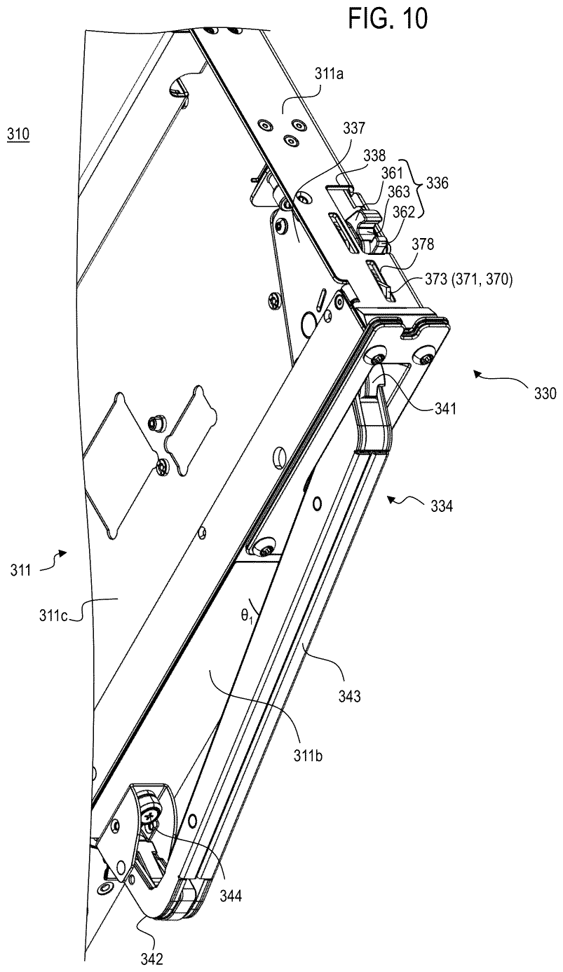

Turning now to FIGS. 10-14, an example latch mechanism 330 and latch interrupt 370 will be described, together with an example information processing device 310. The latch mechanism 330 and latch interrupt 370 are example implementations of the latch mechanisms 130 and 230 and the latch interrupts 170 and 270 described above. Thus, some components thereof are similar to (e.g., example implementations or configuration of) corresponding components already described above. Corresponding components may be referred to using reference numbers having the same last two digits, such as 171 and 371. It should be understood that the latch mechanism 330 and latch interrupt 370 are possible implementations of the latch mechanisms 130 and 230 and latch interrupts 170 and 270, but the latch mechanisms 130 and 230 and latch interrupts 170 and 270 are not limited to these examples.

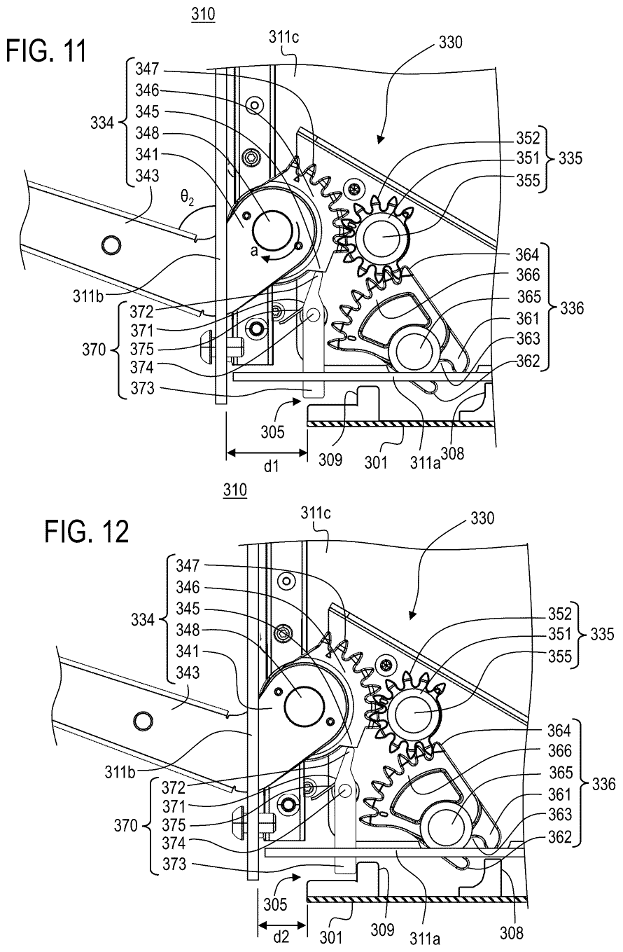

The information processing device 310 is configured to be used as a blade of a larger information processing system with a blade-style architecture, and may be an implementation example of the information processing device 110. As shown in FIG. 10, the information processing device 310 (“blade 310”) comprises a device chassis 311 comprising a base 311c, a side wall 311a, and a front panel 311b, another side wall (not illustrated) opposite the side wall 311a, and a rear panel (not illustrated) opposite the front panel 311b. The device chassis 311 may also include a top cover, which is omitted in the figures to reveal the underlying parts. The device chassis 311 is configured to be removably installed in a bay 305 of a system chassis 301, as shown in FIGS. 11-14. The blade 310 also comprises a system board (not illustrated) to which are mounted information processing components (not illustrated) including a processor.

As shown in FIG. 10, the blade 310 also comprises a latch mechanism 330 disposed at a front-side corner of the device chassis 311. The latch mechanism 330 includes a series of mechanically coupled links including a lever 334, a cam 336, and an intermediate gear 335 (shown in FIG. 11) mechanically coupling the lever 334 to the cam 336. The lever 334 is one example implementation of the actuatable links 134 and 234. The cam 336 is one example implementation of the latching links 136 and 236. The intermediate gear 335 is one example of the intermediate link 135. Portions of the latch mechanism 330 may be housed in and/or supported by a latch housing 337, which is visible in FIG. 10 but removed from the other figures to reveal the underlying parts.

The lever 334 comprises a proximal end portion 341 pivotably coupled to the base 311c by a pivot 348 (see FIG. 11), a distal end portion 342 (see FIG. 10), and a lever handle 343 extending between the proximal end portion 341 and the distal end portion 342. The lever handle 343 and distal end portion 342 are positioned outside the device chassis 311 adjacent a front panel 311b thereof. The proximal end portion 341 is disposed primarily within the device chassis 311, with the lever 334 extending through a hole in the front panel 311b. The proximal end portion 341 further comprises a first gear 346 comprising gear teeth 347.

The lever 334 is actuatable between a latched pose, shown in FIGS. 10 and 14, and an unlatched pose, shown in FIGS. 11-13. The latched pose of the lever 334 corresponds to a latched state of the latch mechanism 330, and the unlatched pose of the lever 334 corresponds to an unlatched state of the latch mechanism 330. Moreover, the latch mechanism 330 is actuated (moved) between the latched and unlatched states by manually pivoting the lever 334 between the latched and unlatched poses.

In the latched pose, the lever handle 343 extends laterally across the front panel 311b with the distal end portion 342 adjacent the front panel 311b, as shown in FIG. 10. Furthermore, in the latched poses, an angle θ₁ between the lever handle 343 and the front panel 311 b (see FIG. 14) is relatively small, such as about 12° in some examples. In addition, in some examples, the distal end portion 342 may include a lock 344 (e.g., a screw), which may be engaged with the front panel 311b when in the latched pose to prevent actuation of the lever 334.

In the unlatched pose, the lever 334 is pivoted such that the lever handle 343 moves away from the front panel 311b, resulting in a much larger angle θ₂ between the lever handle 343 and the front panel 311b, as shown in FIG. 11. For example, θ₂ may be about 72°.

The intermediate gear 335 comprises a gear body 351, gear teeth 352 coupled to gear body 351, and a pivot 355 rotatably coupling gear 335 to base 311c. The gear teeth 352 of the intermediate gear 335 are engaged (meshed) with the gear teeth 347 of the first gear 346 of the lever 334.

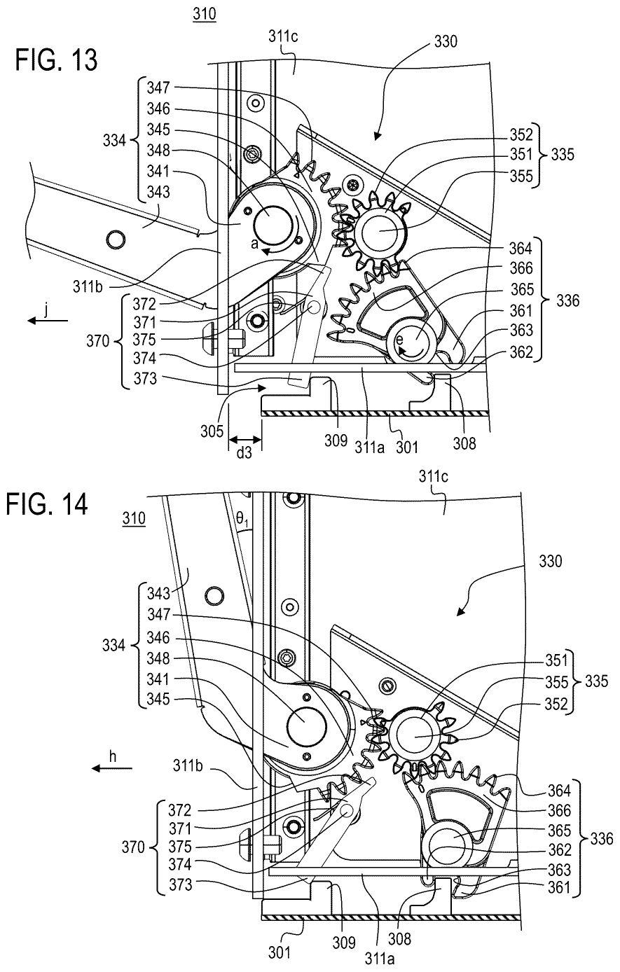

The cam 336 comprises a pivot 365 rotatably coupling the cam 336 to the base 311c. The cam 336 also comprises cam teeth 361 and 362 at one end and a second gear 366 at an opposite end. The cam teeth 361 and 362 define a latching recess 363 therebetween, and these protrude laterally from the side wall 311a of the device chassis 311 via an opening 338, shown in FIG. 10. The cam 336 is rotatable between a latched pose, shown in FIG. 14, and an unlatched pose, shown in FIG. 13. The latched pose of the cam 336 corresponds to the latched state of the latch mechanism 330, while the unlatched pose of the cam 336 corresponds to the unlatched state of the latch mechanism 330. In the latched pose, the cam tooth 361 protrudes laterally through and beyond the side wall 311a (see FIG. 14), whereas in the unlatched pose the tooth 361 does not protrude beyond the side wall 311a (see FIG. 13). Furthermore, in the latched pose, the cam teeth 361 and 362 and the latching recess 363 are positioned to engage with a latching feature 308 of the system chassis 301 to latch the blade 310 in the system chassis 301—i.e., the tooth 361 abuts the latching feature 308 and prevents movement of the blade 310 relative to the system chassis in the direction “h” shown in FIG. 14. In the unlatched pose, the cam tooth 362 may still engage the latching feature 308 but the cam tooth 361 and the latching recess 363 do not, thus releasing the blade 310 from the system chassis 301—i.e., the blade 310 can move relative to the system chassis 301 along direction “j” shown in FIG. 13.

The second gear 366 includes gear teeth 364 that are engaged (meshed) with the gear teeth 352 of the intermediate gear. Thus, pivoting of the lever 334 in a first direction causes rotation of the intermediate gear 335 in an opposite second direction, which in turn causes rotation of the cam 336 in the first direction. Thus, actuation of the lever 334 between its latched and unlatched poses causes the cam 336 to rotate between its latched and unlatched poses, respectively.

The blade 310 also comprises a latch interrupt 370. The latch interrupt 370 comprises an interrupt arm 371 and a pivot 374 pivotably coupling the interrupt arm 371 to the base 311c. The interrupt arm 371 has a first end 372 and a second end 373 opposite the first end 372. The interrupt arm 371 is pivotable between a disabling state, shown in FIGS. 11 and 12, and an enabling state, shown in FIGS. 13 and 14. As shown in FIG. 11, in the disabling state, the first end 372 of the interrupt arm 371 is engaged with a ledge 345 on the proximal end portion 341 of the lever 334 and physically blocks the ledge 345 from moving about pivot 348, thereby preventing rotation of the lever 334 in the direction labeled “a” in the figure. Thus, in the disabling state, the latch interrupt 370 disables actuation of the latch mechanism 230. As shown in FIG. 13, in the enabling state, the first end 372 of the interrupt arm 371 is disengaged from a ledge 345 on the proximal end portion 341 of the lever 334 and no longer blocks it motion, thereby allowing rotation of the lever 334 in the direction labeled “a” in the figure. Thus, in the enabling state, the latch interrupt 370 enables actuation of the latch mechanism 230.

The second end 373 of the interrupt arm 371 is configured to contact a release feature 309 of the system chassis 301 during insertion of the blade 310 into a bay 305 of the system chassis 301. This contact with the release feature 309 causes the interrupt arm 371 to move from the disabling state to the enabling state. Moreover, this change in state occurs automatically based on the position of the blade 310 as the blade 310 is inserted into the system chassis 301, ensuring that the latch mechanism 330 remains disabled until the blade 310 is at an injection-ready position.

The latch interrupt 370 also comprises a spring 375 which biases the interrupt arm 371 towards the disabling state. In the figures, the spring 375 is shown as a torsion spring, but in other examples other types of springs could be used, such as a coil spring, or others.

Aspects of the latch mechanism 330 and the latch interrupt 370 will be described below in relation to an insertion sequence shown in FIGS. 11-14. This insertion sequence in FIGS. 11-14 has insertion stages corresponding to those of the insertion sequences shown in FIGS. 3-5 and 6-9.

FIG. 11 shows a first stage of insertion, which corresponds to the first stage of insertion in FIGS. 3 and 6. In this stage, the latch mechanism 330 is in an unlatched stage and the latch interrupt 370 is in the disabling state. Specifically, the first end 372 of interrupt arm 371 is in contact with the ledge 345 of lever 334 and physically prevents (blocks) rotation of the lever 334 in the direction “a” toward the latched state.

As the blade 310 is advanced from the first stage farther into the system chassis 301, eventually the second end 373 of the interrupt arm 371 collides with the release feature 309. This occurs when the blade 310 is a distance d2 from the fully installed position. This state is shown in FIG. 12 and corresponds to the second stage shown in FIGS. 3 and 7.

As the blade 310 continues to be advanced from the second stage farther into the system, the release feature 309 will push against the second end 373 and rotate the interrupt arm 371 towards the enabling state. Eventually, the first end 372 will move far enough that it will ceases to block the ledge 345. This state is shown in FIG. 13. This pose of the interrupt arm 371 corresponds to the enabling state because the interrupt arm 371 in this pose no longer prevents rotation of the lever 334. This state corresponds to the third stage illustrated in FIGS. 4 and 8. In this stage, the blade 310 is positioned in the bay 305 at an injection-ready position, i.e., a distance d3 from the fully installed position. This means that, in this position, actuation of the latch mechanism 330 to the latched state by rotation of lever 334 in direction “a” will cause the cam 336 to properly engage with the latching feature 308 and insert the blade 310 into the installed position. Specifically, in this position, if the cam 336 rotates in the direction “e,” the tooth 361 will start to move laterally outward and engage with a trailing edge of the latching feature 308, and, with continued rotation, cam tooth 361 will begin to push forward against latching feature 308. This causes a reaction force which pushes the blade 310 to move in rearward relative to system chassis 301, thus moving blade 310 into the installed position.

The installed position of the blade 310 is shown in FIG. 14, and corresponds to the fourth stage illustrated in FIGS. 5 and 9. This position of the blade 310 is reached when the latch mechanism 330 has been moved fully to the latched state. In this state, the latching feature 308 is received in the latching recess 363, with the cam teeth 361 and 362 on opposite sides thereof, thus latching the blade 310 to the system chassis 301. Moreover, the latch interrupt 370 is held in the enabled state, allowing actuation of the latch mechanism 330.

Note that in FIGS. 2-9 and 11-14, the distances d1, d2, d3, and d4 are labeled. The same labels are used in multiple figures to indicate that the illustrated positions correspond to one another conceptually. For example, FIGS. 4, 8, and 13 all show injection-ready positions of a blade in a bay, and this position is conceptually indicated by the blade being a distance “d3” from the installed position. However, the actual physical distance which d3 represents can vary from one example to another, and a distance labeled d3 in one figure is not necessarily limited by a distance labeled d3 in another figure. In other words, the labels d1, d2, d3, and d4 indicate conceptually corresponding positions in stages of insertion of the blade into a bay, but are not meant to reflect specific or fixed numerical values.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An information processing device comprising;
a device chassis that is removably installable in a system chassis;
a latch mechanism coupled to the device chassis and comprising mechanically coupled links that are:
actuatable from an unlatched state to a latched state to inject the device chassis to an installed position in the system chassis and secure the device chassis in the installed position, and
actuatable from the latched state to the unlatched state to eject the device chassis from the installed position; and
a latch interrupt coupled to the device chassis and configured to selectively disable and enable actuation of the latch mechanism by engagement with and disengagement from one of the links, respectively, based on a position of the device chassis within the system chassis.

2. The information processing device of claim 1,
wherein the latch interrupt is configured to engage a release feature of the system chassis during insertion of the device chassis into the system chassis and to be moved by the engagement from a disabling state, in which the latch interrupt disables actuation of the latch mechanism, to an enabling state, in which the latch interrupt enables actuation of the latch mechanism.

3. The information processing device of claim 2,
wherein the latch interrupt is configured to automatically move from the enabling state to the disabling state in response to actuation of the latch mechanism from the latched state to the unlatched state followed by movement of the information processing device away from an injection-ready position.

4. The information processing device of claim 2,
wherein the latch interrupt comprises an interrupt arm pivotably coupled to the device chassis, a first end of the interrupt arm is configured to engage the one of the links in the disabling state, a second end of the interrupt arm is configured to contact the release feature, and motion of the latch interrupt between the disabling and enabling states comprises pivoting of the interrupt arm.

5. The information processing device of claim 4,
wherein the latch interrupt comprises a spring coupled to the interrupt arm and to the device chassis and configured to apply a spring force biasing the interrupt arm to the disabling state.

6. The information processing device of claim 4,
wherein the second end of the interrupt arm protrudes laterally from a side wall of the device chassis and is accessible from outside the device chassis to allow manual actuation of the latch interrupt from the disabling state to the enabling state.

7. The information processing device of claim 2,
wherein the latch interrupt is arranged to be moved to the enabling state, by the engagement with the release feature, upon the device chassis reaching an injection-ready position in the system chassis, and
wherein the injection-ready position comprises a position of the device chassis at which the latch mechanism can engage with a latching protrusion of the system chassis to inject the device chassis to the installed position.

8. The information processing device of claim 7,
wherein, in the injection-ready position, movement of the latch mechanism from the unlatched state to the latched state causes the latch mechanism to inject the device chassis to the installed position by the latch mechanism applying a first force in a first direction to the latching protrusion; and
wherein, in the installed position, movement of the latch mechanism from the latched state to the unlatched state causes the latch mechanism to eject the device chassis to the injection-ready position by the latch mechanism applying a second force in a second direction to the latching protrusion.

9. The information processing device of claim 2,
wherein the latch interrupt comprises an interrupt arm movably coupled to the device chassis, a first end of the interrupt arm is configured to engage the one of the links in the disabling state, a second end of the interrupt arm is configured to contact the release feature, and motion of the latch interrupt between the disabling and enabling states comprises translation of the interrupt arm.

10. The information processing device of claim 1, wherein the links of latch mechanism include:
a lever comprising a first gear, the lever pivotable relative to the device chassis to actuate the latch mechanism;
a cam comprising a second gear, wherein the cam is pivotable relative to the device chassis between a first pose corresponding to the latched state and a second pose corresponding to the unlatched state, and the cam is configured to engage with the system chassis to inject and eject the device chassis; and
one or more intermediate gears mechanically coupling the first gear to the second gear.

11. The information processing device of claim 10,
wherein the one of the links that the latch interrupt engages to disable actuation of the latch mechanism comprises the lever.

12. The information processing device of claim 11,
wherein the lever comprises a proximal end and a distal end, the proximal end is pivotably coupled to the device chassis and comprises the first gear, the distal end comprises a handle manually actuatable to pivot the lever, and
wherein the proximal end of the lever comprises a ledge configured to engage with the latch interrupt in a disabling state of the latch interrupt and the unlatched state of the latch mechanism.

13. The information processing device of claim 10,
wherein the one of the links that the latch interrupt engages to disable actuation of the latch mechanism comprises the cam.

14. The information processing device of claim 10,
wherein the one of the links that the latch interrupt engages to disable actuation of the latch mechanism comprises one of the one or more intermediate gears.

15. An information processing system comprising:
a system chassis comprising a plurality of bays configured to receive information processing devices pluggably installed therein;
an information processing device comprising:
a device chassis that is removably installable in one of the bays of the system chassis;
a latch mechanism coupled to the device chassis and comprising mechanically coupled links that are:
actuatable from an unlatched state to a latched state to inject the device chassis to an installed position in the system chassis and secure the device chassis in the installed position, and
actuatable from the latched state to the unlatched state to eject the device chassis from the installed position; and
a latch interrupt coupled to the device chassis and configured to selectively disable and enable actuation of the latch mechanism by engagement with and disengagement from one of the links, respectively, based on a position of the device chassis within the system chassis.

16. The information processing system of claim 15,
wherein each of the bays comprises a release feature arranged to contact the latch interrupt in response to insertion of the information processing device into the respective bay and to move, by the engagement, the latch interrupt from a disabling state, in which the latch interrupt disables actuation of the latch mechanism, to an enabling state, in which the latch interrupt enables actuation of the latch mechanism.

17. The information processing system of claim 16,
wherein, for each of the bays, the release feature is arranged to move the latch interrupt to the enabling state upon the device chassis reaching an injection-ready position in the bay comprising a position of the device chassis at which the latch mechanism can engage with a latching protrusion of the system chassis in the bay to inject the device chassis to the installed position.

18. The information processing system 15, wherein the links of latch mechanism include:
a lever comprising a first gear, the lever pivotable relative to the device chassis to actuate the latch mechanism;
a cam comprising a second gear, wherein the cam is pivotable relative to the device chassis between a first pose corresponding to the latched state and a second pose corresponding to the unlatched state, and the cam is configured to engage with the system chassis to inject and eject the device chassis; and
one or more intermediate gears mechanically coupling the first gear to the second gear.

19. A method of operating an information processing system, comprising, inserting a blade into a bay of a system chassis of the information processing system while a latch mechanism of the blade is in an unlatched state and a latch interrupt of the blade is in a disabling state in which the latch interrupt disables actuation of the latch mechanism by engagement with a link of the latch mechanism;
advancing the blade into the bay to an injection-ready position and causing a release feature of the system chassis to engage with the latch interrupt and move the latch interrupt to an enabling state upon the blade reaching the injection-ready position, wherein in the enabling state the latch interrupt is disengaged from the link and actuation of the latch mechanism is enabled; and
injecting the blade from the injection-ready position into an installed position in the bay by actuating the latch mechanism from the unlatched state to a latched state.

20. The method of claim 19, comprising,
ejecting the blade from the installed position to the injection-ready position by actuating the latch mechanism from the latched state to the unlatched state while the latch interrupt is in the enabling state; and
causing the latch interrupt to automatically move to the disabling state by moving the blade away from the injection-ready position with the latch mechanism in the unlatched state.
